(19) United States
(12) Patent Application Publication
(10) Pub. No.: US 2007/0117292 A1
(43) Pub. Date: May 24, 2007

(54) Display device and fabrication method thereof

(75) Inventors: Yasukazu Kimura, Chiba (JP); Toshihiko Itoga, Chiba (JP); Takeshi Noda, Mobara (JP)

Correspondence Address: Stanley P. Fisher;Reed Smith LLP, Suite 1400, 3110 Fairview Park Drive, Falls Church, VA, 22042-4503, US

(73) Assignee: Hitachi Displays, Ltd.

(21) Appl. No.: 11/593,552

(22) Filed: Nov. 7, 2006

(30) Foreign Application Priority Data
Nov. 18, 2005 (JP) 2005-334164

(51) Int. Cl. H01L 21/84; H01L 27/148

(52) U.S. Cl. 438/166; 257/223

(57) ABSTRACT

The present invention provides a display-device-use substrate which is strip-crystallized while minimizing the generation of peeling of a semiconductor by suppressing the generation of aggregation at the time of crystallization due to the radiation of continuous oscillation laser beams. A silicon nitride film and a silicon oxide film which constitutes a background film are formed on a glass substrate on which projecting portions are formed, and a silicon base film is formed on the silicon nitride film and a silicon oxide film. Banks which intersect the scanning directions of laser beams are positioned below the silicon base substrate. The aggregation which is generated by the scanning of laser beams is stopped at a portion after the laser beams gets over the bank and, thereafter, the strip crystal silicon film is formed normally.

The present application claims priority from Japanese application JP2005-334164 filed on Nov. 18, 2005, the content of which is hereby incorporated by reference into this application.

### BACKGROUND OF THE INVENTION

The present invention relates to a display device having drive circuits, a pixel circuit or other various circuits which are made of high-quality thin film transistors by crystallizing a semiconductor film formed on an insulation substrate by radiating laser beams to the semiconductor film, and a fabrication method of the display device.

There have been popularly used active matrix type display devices (or display devices of an active matrix drive method) which use active elements such as thin film transistors as drive elements of pixels which are arranged in a matrix array. Many of these display devices display images of high quality by arranging a large number of pixel circuits and drive circuits for supplying signals for display to the pixel circuits which are constituted of an active element such as a thin film transistor (TFT) which is formed using a silicon film as a semiconductor film on the insulation substrate made of glass or the like. Here, the explanation is made hereinafter by taking the thin film transistors which constitute a typical example of the active elements.

In the thin film transistor which uses a generally-used amorphous silicon semiconductor film (an a-Si film) as a semiconductor film, the performance of the thin film transistor is limited with respect to the mobility of carriers (electrons or holes) and hence, it is difficult to constitute a circuit which copes with a demand for a high operational speed and a high function. To realize the thin film transistor of high mobility necessary for providing the more excellent image quality, it is effective to reform the amorphous silicon film into a poly-silicon film (also referred to as a polycrystalline silicon film, a p-Si film) (here, granular crystallization) and to form the thin film transistor using this poly-silicon film. To perform such a reform, a technique which anneals the amorphous silicon film by radiating laser beams such as excimer laser beams to the amorphous silicon film (excimer laser annealing, ELA) has been used.

The ELA is a method in which an amorphous silicon film is stacked (or formed) on an insulation substrate by way of a background film (made of SiN, SiO₂ or the like), line-like excimer laser beams having a width of several nm to 100 nm are radiated to the amorphous silicon film, and by performing scanning which moves the radiation position for every 1 to several pulses along one direction thus annealing the amorphous silicon film whereby the amorphous silicon film formed on the insulation substrate is reformed to the poly-silicon film. By applying various treatment such as etching, formation of lines, ion implantation and the like to the poly-silicon film which is reformed by the method, it is possible to form the circuit which has active element such as the thin film transistor in a pixel part or a drive part or the like which constitutes the display device.

Using the insulation substrate acquired in this manner, an active-matrix-type image forming apparatus such as a liquid crystal display device, an organic EL display device or the like is fabricated. In reforming the silicon film using the conventional excimer laser beams, at a portion to which the laser beams are irradiated, a large number of silicon particles (poly-silicon particles) which are crystallized with a particle size of approximately 0.05 μm to 0.5 μm grow at random. A field effect mobility of electrons of the TFT made of such a poly-silicon film is equal to or less than 200 cm²/Vs and the average field effect mobility is approximately 120 cm²/Vs.

Further, as a method for acquiring a high-quality semiconductor film, as described in J-P-A-2003-86505 (patent document 1), by radiating the continuous oscillation laser beams (CW laser beams) to a semiconductor film while scanning the continuous oscillation laser (a CW laser), crystals in one direction which are continuous in the scanning direction are grown thus forming strip crystal which are elongated in the direction (also referred to as “lateral crystals”. Further, it is possible to obtain strip crystal in which flat crystalline particles largely grow in one direction by a method in which the substrate is scanned while radiating CW laser beams to the semiconductor film which is preliminarily formed in an island shape or a linear shape or a method which imparts a thermal gradient at the time of performing laser annealing. The electrons of TFTs which use such a semiconductor film exhibit the high-performance characteristics, that is, the field effect mobility of approximately 300 cm²/Vs or more.

Here, J-P-A-2003-282437 discloses a technique which forms a poly-silicon film having larger crystals than a conventional poly-silicon film by radiating laser beams to an amorphous silicon film which is formed on an insulation substrate while scanning.

FIG. 16 is a schematic view showing the manner of crystallization of a semiconductor film using a continuous oscillator laser. On a glass substrate 101 which constitutes an insulation substrate, for preventing the lift of potassium (Na) impurities from glass, a background film which is constituted of a silicon nitride film (SiN) film 102 and a silicon oxide film (SiO₂) film 103 is formed. A silicon film (also referred to as a silicon base film or a precursor film) 107 to which laser annealing is applied is formed on the background film. The silicon base film 107 is not limited to an amorphous silicon film which is formed by CVD and may be a poly-silicon film 301 which is obtained by crystallizing the amorphous silicon film using ELA.

By radiating the continuous oscillation beams 303 to the silicon base film 107, a high-quality polycrystalline silicon layer which is elongated flatly along the scanning direction S of the laser (strip crystal) 302 is acquired. Here, a stay time of laser at one point on the silicon base film 107 of the glass substrate becomes a value which falls within a range from several μs to several hundred μs. The melting time of the silicon base film 107 is also considered to be the approximately equally elongated time and the melting time is far longer than time for crystallization by ELA using a pulse laser. Accordingly, the melted silicon is coagulated thus generating the aggregation and portions which are peeled by the aggregation.

FIG. 17A and FIG. 17B are conceptual views of the aggregation and the peeling which are generated by the continuous oscillation laser, wherein FIG. 17A is a plan view and FIG. 17B is a cross-sectional view taken along a line A-A′ in FIG. 17A. Parts identical with the parts shown in FIG. 16 are indicated by same symbols. In the above-mentioned laser radiation, when the above-mentioned background film is used, portions 304 where silicon is coagulated and portions 305 where silicon is peeled are generated. Since the silicon layer is not present in the peeling portion 305, even when a thin film transistor is built in the portion, the thin film transistor is not operated and hence, a whole panel becomes defective. The occurrence frequency of the aggregation is approximately 1.4 pieces/cm².

With respect to the polycrystallization, there has been known a technique disclosed in J-P-A-2003-158135 (patent document 3) in which an amorphous silicon film is polycrystallized by ELA after the amorphous silicon film is dehydrated and a silicon oxide film having a thickness of 1 to 10 nm is formed as a cap layer by removing a natural oxide film. However, the technique disclosed in patent document 3 completely fails to take the aggregation and peeling which are generated by the continuous oscillation laser into consideration. Further, the related art on the generation of strip crystal using the continuous oscillation laser is disclosed in J-P-A-2002-222959 (patent document 4), J-P-A-2003-124136 (patent document 5) or J-P-A-2003-86505 (patent document 1). Further, J-P-A-2003-257865 (patent document 6) discloses a technique which forms an insulation film having uneven steps on a substrate and concentrates strains or stresses which are generated attributed to the crystallization of a semiconductor film to stepped portions thus selectively forming favorable crystals in a recessed flat portion.

### SUMMARY OF THE INVENTION

In the conventional laser crystallization method, in an attempt to form a high-quality uniform semiconductor thin film on the whole surface of the glass substrate having a large area used in the manufacture of an image display device, attributed to the instability or the non-uniformity of the film or the instability or the non-uniformity of laser radiation condition, there arise drawbacks such that a portion of the film is peeled off due to the aggregation in liquid Si (hereinafter referred to as “aggregation”) or the semiconductor thin film is not grown laterally thus generating granular crystals. Particularly, when a film thickness of the semiconductor thin film is 200 nm or less, heat generated by laser radiation leaks to the base substrate side and hence, there arises a drawback that the coagulation attributed to cooling progresses rapidly, the crystalline nucleus are generated naturally before the growth of lateral crystals and hence, large particles are not acquired. Further, when the radiation time is prolonged or when the excessive laser fluence is applied, there also arises a drawback that the aggregation is liable to be easily generated or a drawback that thermal stresses or damages are applied to a background film.

As explained also in conjunction with FIG. 17, the above-mentioned aggregation is a phenomenon that a silicon film which is melted at the time of crystallization due to laser radiation is pulled up by a surface tension and hence, portions where the silicon film is not present (peeled portions) are formed on the substrate surface. The aggregation may be either in a spot shape or in a stripe shape due to a film quality of the background film or the silicon film. Although it is necessary to provide a process which prevents the generation of such aggregation, it is difficult to completely eliminate the aggregation. Once the aggregation is generated, there may arise a worst situation in which the aggregation cannot be stopped until the crystallization of the region is completed. As a result, a yield rate of the crystallization is remarkably lowered as a matter of course. Since the substrate on which the aggregation is generated is no more reproducible, the lowering of the yield rate is particularly remarkable with respect to a large-sized substrate for television receiver set which has a large crystallizing area.

Here, to suppress the generation of the aggregation, a background film which exhibits the favorable wettability with silicon is formed on the substrate or a cap layer is formed on a silicon film. However, it has been pointed out that the mounting of the cap layer on the silicon film lowers the characteristics of the thin film transistor.

The present invention has been made under such circumstances and it is an object of the present invention to provide a fabrication method which can acquire a display-device-use substrate which performs strip crystallization by minimizing the generation of peeling of a semiconductor by suppressing the generation of aggregation at the time of crystallization attributed to the radiation of continuous oscillation laser beams and a high-quality display device which is fabricated by the fabrication method.

To achieve the above-mentioned object, the present invention forms a projecting step in an insulation substrate or in an insulation film formed on the insulation substrate. When the projecting step is formed in the insulation substrate, an insulation film is further formed on the projecting step and, thereafter, a silicon film (a silicon base film=a precursor film) is formed on the insulation film. When projecting step is formed on the insulation film formed on the insulation substrate, a silicon film is formed on the insulation film. Next, the lateral crystallization is performed by radiating the continuous oscillation laser beams after crystallizing the silicon film by ELA or without crystallizing the silicon film by ELA.

Hereinafter, examples of the constitution of the present invention are enumerated. First of all, in a fabrication method of a display device, a bank is formed on a substrate or a substrate on which an insulation film is formed, and a semiconductor film is formed such that the semiconductor film covers the bank and a flat portion except for the bank. While radiating the continuous oscillation laser beams to the semiconductor film, the scanning is performed traversing the bank in the direction which intersects the longitudinal direction of the bank at an angle of 30 degrees or more and 90 degrees or less thus forming strip crystal on the semiconductor film.

The strip crystal is formed such that while radiating the continuous oscillation laser beams to the semiconductor film, the scanning may be preferably performed traversing the bank in the direction which intersects the longitudinal direction of the bank at an angle of 60 degree or more and 90 degrees or less. The scanning may be performed in the direction which intersects the longitudinal direction of the bank at an angle of 30 degrees or more and 60 degrees or less by arranging the positions where the banks are formed and the direction of the banks.

When the fabrication method includes a cutting step in which the substrate is cut into a plurality of display devices, the bank may be formed along the cut portions. Further, the bank may be formed in the vicinity of the cut portions.

A height of the bank is set to 20 nm or more (preferably equal to or more than a film thickness of a silicon base film, for example, 50 nm or more in general) and a tapered angle may be set to 10 degrees or more (preferably 40 degrees or more).

The scanning of the continuous oscillation laser beams is performed by moving either one of the radiation beams or the substrate. Here, the continuous oscillation laser beams are radiated to the semiconductor film while modulating the continuous oscillation laser beams into pulses.

Further, the display device of the present invention includes a semiconductor film having strip crystal which are formed on an insulation film formed on a substrate, wherein

a bank is formed on the substrate or the insulation film, and the longitudinal direction of the bank intersects an extension of the strip crystal in the longitudinal direction at an angle of 30 degrees or more and at an angle of 90 degrees or less, preferably at an angle of 60 degrees or more and 90 degrees or less. However, by arranging the position where the bank is formed and the direction of the bank, the longitudinal direction of the bank may intersect the extension of the strip crystal in the longitudinal direction at an angle of 30 degrees or 60 degrees or less.

The bank may be formed along a side of the substrate and may be formed at a position in the vicinity of the side of the substrate along the side of the substrate.

Due to the above-mentioned constitutions, it is possible to form the strip crystal at a flat portion where the bank is not formed by performing the scanning of the continuous oscillation laser beams by traversing the bank.

Here, the present invention is not limited to the above-mentioned constitutions and the constitutions which are described in the detailed explanation of the present invention described later and various modifications can be made without departing from the technical concept of the present invention described in claims.

In performing the crystallization by the continuous oscillation laser beams, when the aggregations is continuously generated by laser scanning, the projecting portion (stepped portion) is formed in the direction orthogonal to the scanning direction of the crystallization and hence, the silicon film which is aggregated at a neck portion where the descending step (a descending inclined surface) reaches a recessed bottom portion (a boundary portion between the descending inclined surface and the recessed bottom portion) spreads along the neck portion in the direction parallel to the neck portion thus acquiring an advantageous effect that the normal crystallization is again acquired at the recessed portion (the recessed bottom portion). A phenomenon that the silicon film spreads at the neck portion of the recessed bottom portion of the descending step is considered to be derived from a fact that silicon which is melt by energy of the laser beams flows down toward the neck portion from a wall surface of the descending step so that a volume of the melted silicon at the neck portion is increased so that the melted silicon obtains a force which makes the melted silicon spread along the neck portion in the direction parallel to the neck portion. However, the accurate principle is not yet clarified.

The aggregation is a non-reproducible phenomenon and hence, when a channel or source/drain regions of the thin film transistor are formed in the aggregation portion, the aggregation makes a circuit constituted of the thin film transistor inoperative. According to the present invention, it is possible to minimize a region where the aggregation is generated thus largely contributing to the enhancement of a yield rate of a display device.

### BRIEF DESCRIPTION OF THE DRAWING

FIG. 1A and FIG. 1B are conceptual views for explaining a principle of the present invention;

FIG. 2A to FIG. 2D are views for explaining an essential part of a fabrication method of a display device of the present invention;

FIG. 3A and FIG. 3B are views for explaining a measuring method of an intersecting angle of the longitudinal direction of a bank formed on a substrate and the scanning direction of laser beams;

FIG. 4A and FIG. 4B are views for explaining a measuring method of a tapered angle of a silicon base film formed on the bank;

FIG. 5 is a view for explaining a measuring method of an intersecting angle of an extension of the longitudinal direction of a bank and an extension of strip crystal in the longitudinal direction;

FIG. 6 is a view for schematically explaining an embodiment 1 of a layout of the bank on the substrate used in the display device according to the present invention;

FIG. 7 is a plan view showing a portion of FIG. 6 in an enlarged manner;

FIG. 8 is a plan view for schematically explaining an embodiment 2 of a layout of the bank on the substrate used in the display device according to the present invention;

FIG. 9 is a view for schematically explaining an embodiment 3 of a layout of the bank on the substrate used in the display device according to the present invention;

FIG. 10 is a schematic view for explaining the generation of the aggregation in the embodiment 3 shown in FIG. 9 and the suppression of the generation of the aggregation;

FIG. 11 is a view for schematically explaining an embodiment 4 of a layout of the bank on the substrate used in the display device according to the present invention;

FIG. 12A to FIG. 12D are views for explaining the various cross sections of a glass substrate on which a silicon film is formed in respective embodiments of the present invention;

FIG. 13 is a cross-sectional view for schematically explaining the constitution of an essential part of an active substrate which constitutes the display device of the present invention;

FIG. 14 is an explanatory view of a constitutional example of a circuit which is formed on the glass substrate of the display device which is fabricated by the fabrication method of the present invention;

FIG. 15 is a schematic view for explaining a constitutional example of a liquid crystal display device as an embodiment of a display device fabricated in accordance with the present invention; and

FIG. 16 is a schematic view showing the manner of crystallization of a semiconductor thin film using continuous oscillation laser beams; and

FIG. 17A and FIG. 17B are conceptual views of aggregation and peeling which are generated by the continuous oscillation laser beams.

### DESCRIPTION OF THE PREFERRED EMBODIMENTS

Hereinafter, embodiments of the present invention are explained in detail in conjunction with drawings showing the embodiments. Here, although the use of a silicon (Si) film is mainly expected as a semiconductor thin film, it is possible to obtain the substantially same advantageous effects by using Ge, SiGe, a compound semiconductor, chalcogenide or the like as a thin film material. In the embodiments explained hereinafter, the explanation is made with respect to a case in which the semiconductor thin film is made of a silicon film. Further, in the present invention, the present invention is not limited to the reforming of an amorphous semiconductor film or a polycrystalline semiconductor film which is formed on an insulation substrate made of glass or the like for a display device and may be applicable in the same manner to the reforming of a semiconductor film which is formed on other substrate such as a plastic substrate or a silicon wafer in the same manner.

Here, as laser beams used here, second-harmonic-wave solid laser beams (wavelength λ=532 nm) of an LD (laser diode) excited Nd:YVO₄ laser with the continuous oscillation (CW) are expected to be used. However, it is desirable to use laser beams which have a wavelength being absorbed by amorphous silicon (a-Si) or poly-silicon (p-Si) semiconductor film, that is, a wavelength in a region ranging from 200 nm to 700 nm. To be more specific, the second harmonic wave, the third harmonic wave, the fourth harmonic wave or the like of a Nd:YAG laser, the Nd:YVO₄ laser or a Nd:YLF laser are applicable. However, to take the magnitude and the stability of the output into consideration, it is preferable to use the second harmonic wave (wavelength λ=532 nm) of the LD excited Nd:YAG laser beams or the second harmonic wave (wavelength λ=532 nm) of the Nd:YVO4 laser beams. Further, it is possible to acquire the substantially equal advantageous effects by using excimer laser beams, Argon laser beams, semiconductor laser beams, solid pulse laser beams or the like.

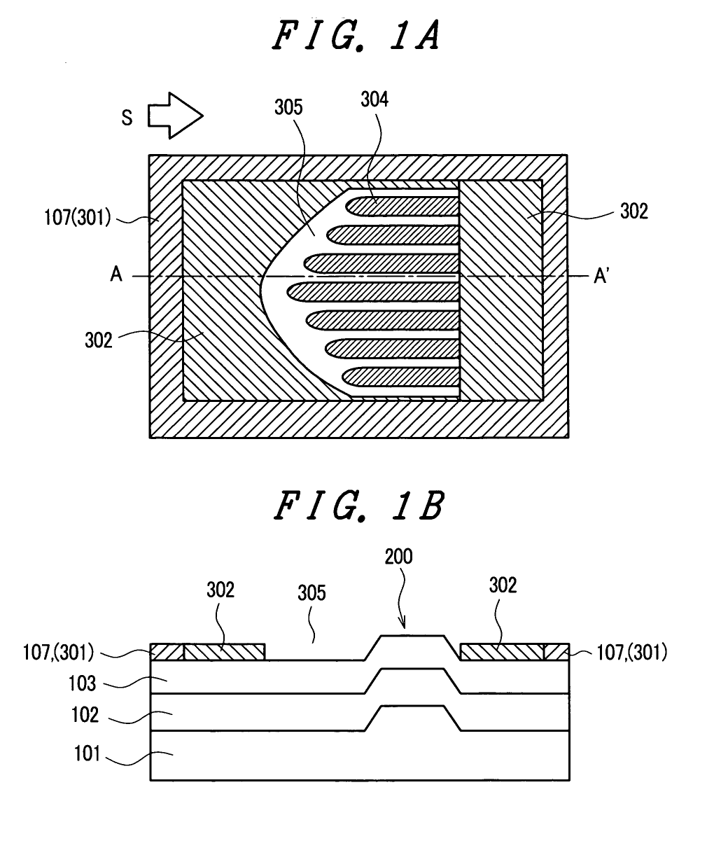

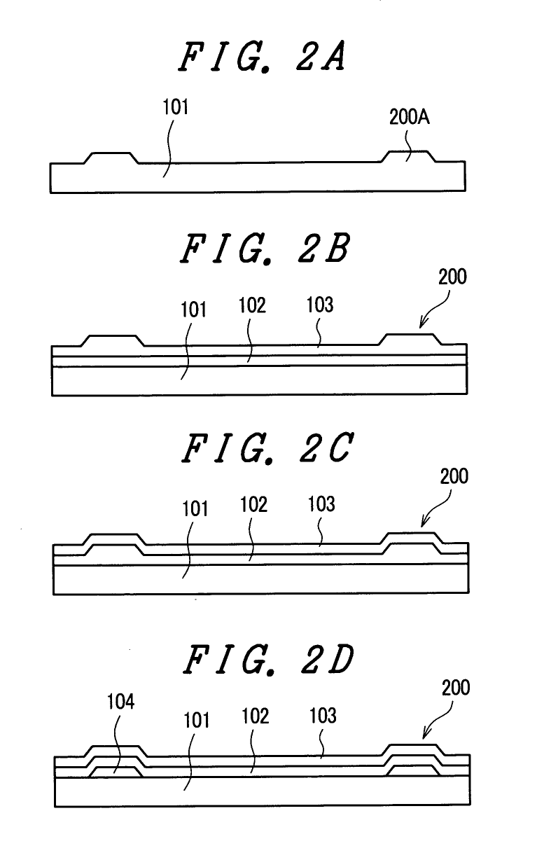

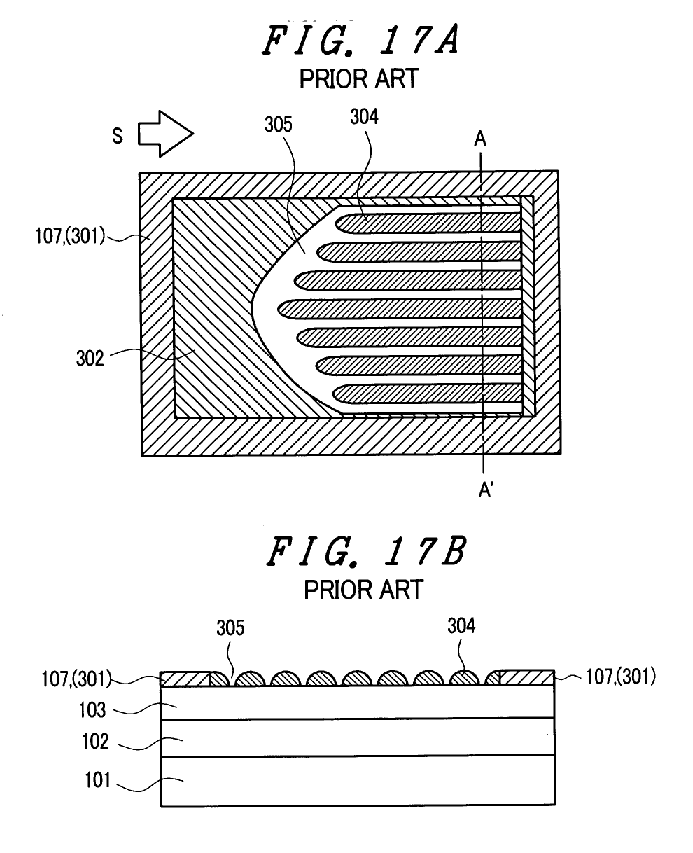

FIG. 1A and FIG. 1B are conceptual views in the same manner as FIG. 17 which explains the principle of the present invention, wherein FIG. 1A is a plan view and FIG. 1B is a cross-sectional view taken along a line A-A′ in FIG. 1A. Parts indicated by the same symbols are identical with the parts shown in FIG. 17, wherein numeral 200 indicates a bank (a projecting step). As explained in conjunction with FIG. 17, when the bank 200 which intersects the scanning direction of the laser beams exists below a silicon base film 107, an aggregation 304 which is continuously generated is stopped at a portion after getting over the bank 200 and, thereafter, the normal crystallization is performed. The present invention minimizes the generation of the aggregation by making use of this phenomenon.

FIG. 2A to FIG. 2D are views for explaining an essential part of a fabrication method of a display device of the present invention and shows several processes for forming banks 200 which intersect the scanning direction of the laser beams below the silicon base film. In the process shown in FIG. 2A, patterning is performed such that the resist is formed on the surface of a glass substrate 101 which constitutes an insulation substrate while covering bank forming portions, and a projecting portion 200A is formed using a glass etchant such as fluoric acid. Thereafter, as shown in FIG. 1, a silicon nitride (SiN) film 102 and a silicon oxide (SiO₂) film 103 are formed as a background film. On a surface of the background film, the banks 200 which reflect the projecting portions 200A on the glass substrate are formed. The silicon base film 107 is formed on the background film and the laser beams are radiated to the silicon base film 107.

The process shown in FIG. 2B shows another method for forming the banks. The above-mentioned projecting portions 200A are not formed on the glass substrate 101 and the SiN film 102 which constitutes a first layer of the background film is formed on the glass substrate 101. The SiO₂ film 103 which constitutes a second layer of the background film is formed on the SiN film 102, and a patterning is performed such that the SiO₂ film 103 is not completely removed and partially remains except for a portion which becomes the banks 200. The SiO₂ film 103 is not completely removed for preventing a following drawback. That is, unless a certain amount of distance is ensured between the silicon base film and the SiN film 102, due to fixed charges in the SiN film 102, the characteristics of a TFT device becomes unstable. This patterning is performed in the same manner as the process shown in FIG. 2A. That is, the patterning is performed such that the resist remains to cover the bank forming portions using an etchant such as a fluoric acid. Due to such a process, it is possible to obtain the bank 200 which is formed by stacking the SiN film 102 and the SiO₂ film 103. The silicon base film 107 is formed on the background film and the laser beams are radiated to the silicon base film 107.

FIG. 2C shows another method for forming the banks. The SiN film 102 which constitutes a first layer of the background film is formed on the glass substrate 101. A patterning is performed such that the SiN film 102 is not completely removed and partially removed except for portions which become the banks 200. The SiN film 102 is not completely removed for allowing the SiN film 102 to ensure a certain film thickness to prevent a lift of potassium (Na) impurities from the glass substrate. The SiO₂ film 103 which constitutes the second layer is formed on the SiN film 102. This patterning is performed in the same manner as the process shown in FIG. 2A. That is, the patterning is performed such that the resist remains to cover the bank forming portions using an etchant such as a fluoric acid or by dry etching. Due to such a process, it is possible to obtain the bank 200 which is formed by stacking the SiN film 102 and the SiO₂ film 103. The silicon base film 107 is formed on the background film and the laser beams are radiated to the silicon base film 107.

FIG. 2D shows another method for forming the banks. An insulation film 104 or a metal film 104 is formed on the glass substrate 101. A patterning is performed such that the insulation film 104 or the metal film 104 is removed except for portions which become the banks 200. This patterning is performed in the same manner as the process shown in FIG. 2A. That is, the patterning is performed such that the resist remains to cover the bank forming portions using an etchant such as a fluoric acid or by dry etching. The SiN film 102 which constitutes the first layer of the background film is formed on the insulation film 104 or the metal film 104 and the SiO₂ film 103 which constitutes the second layer of the background film is formed on the SiN film 102. Due to such a process, it is possible to obtain the bank 200 which is formed by stacking the SiN film 102 and the SiO₂ film 103. The silicon base film 107 is formed on the background film and the laser beams are radiated to the silicon base film 107.

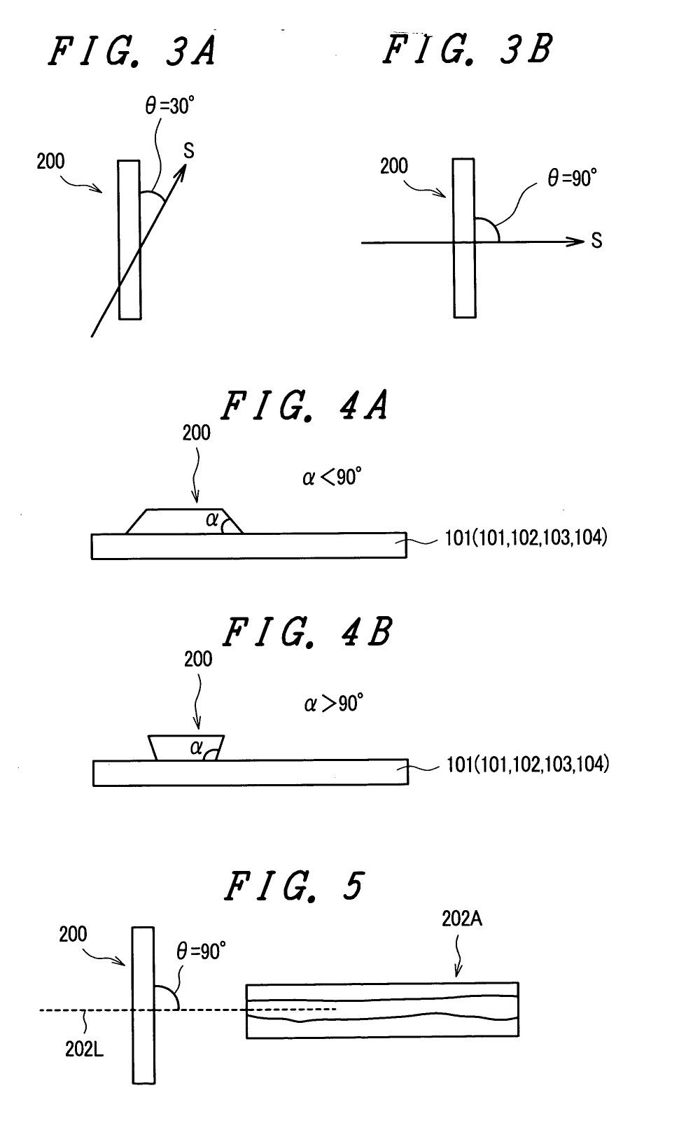

FIG. 3A and FIG. 3B are views for explaining a measuring method of an intersecting angle between the longitudinal direction of the bank formed on the substrate and the scanning direction of the laser beams. In the present invention, the above-mentioned semiconductor film 107 (or 301) is radiated and scanned with continuous oscillation laser beams in the direction S which intersects the longitudinal direction of the banks 200 at an angle of 30° (FIG. 3A) or more and 90° (FIG. 3B) or less while traversing the bank 200. Due to such a process, strip crystal are formed in the semiconductor film 107 (or 301).

FIG. 4A and FIG. 4B are views for explaining a measuring method of a tapered angle of the silicon base film formed on the bank. As shown in FIG. 4A, a tapered angle α of the silicon base film which is formed on the bank 200 which constitutes a background of the silicon base film (the glass substrate 101, the SiN film 102, the SiO₂ film 103 and the insulation film or the metal film 104) is an angle illustrated in the drawings. The tapered angle α is set to a value equal to or less than 90° and equal to or more than 10°. Here, as shown in FIG. 4B, the angle α may be set to α>90°, that is, the angle α may be an inversely tapered angle. It is needless to say that when the silicon base film is formed on the bank 200 shown in FIG. 4B and the step of the silicon base film is terminated at the inversely tapered portion of the bank 200, the aggregation is stopped here and the normal strip crystal silicon film is formed thereafter.

FIG. 5 is a view for explaining a measuring method of an intersecting angle of the longitudinal direction of the bank and the extension of the strip crystal in the longitudinal direction. In FIG. 5, numeral 202L indicates the extension of the strip crystal 202A in the longitudinal direction and intersects the longitudinal direction of the bank 200 at an angle of 30° or more and 90° or less. FIG. 5 shows a case in which the intersecting angle is 90°.

### EMBODIMENT 1

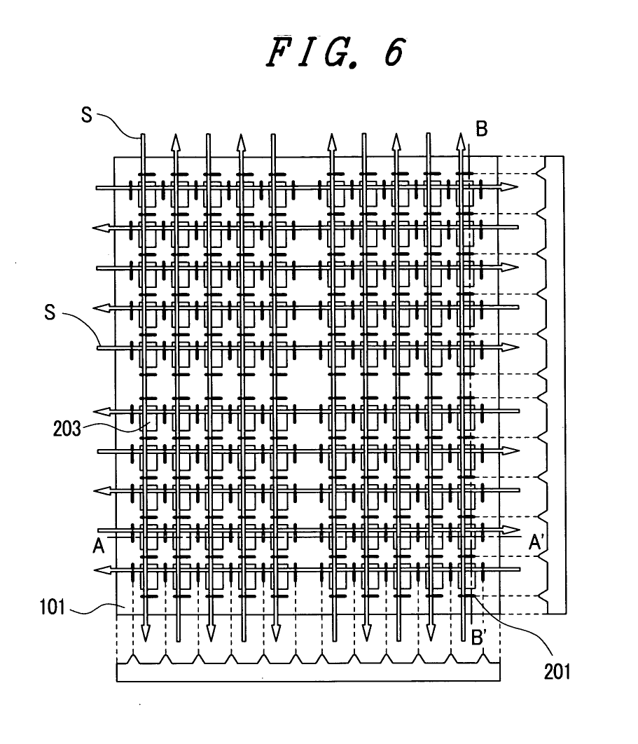

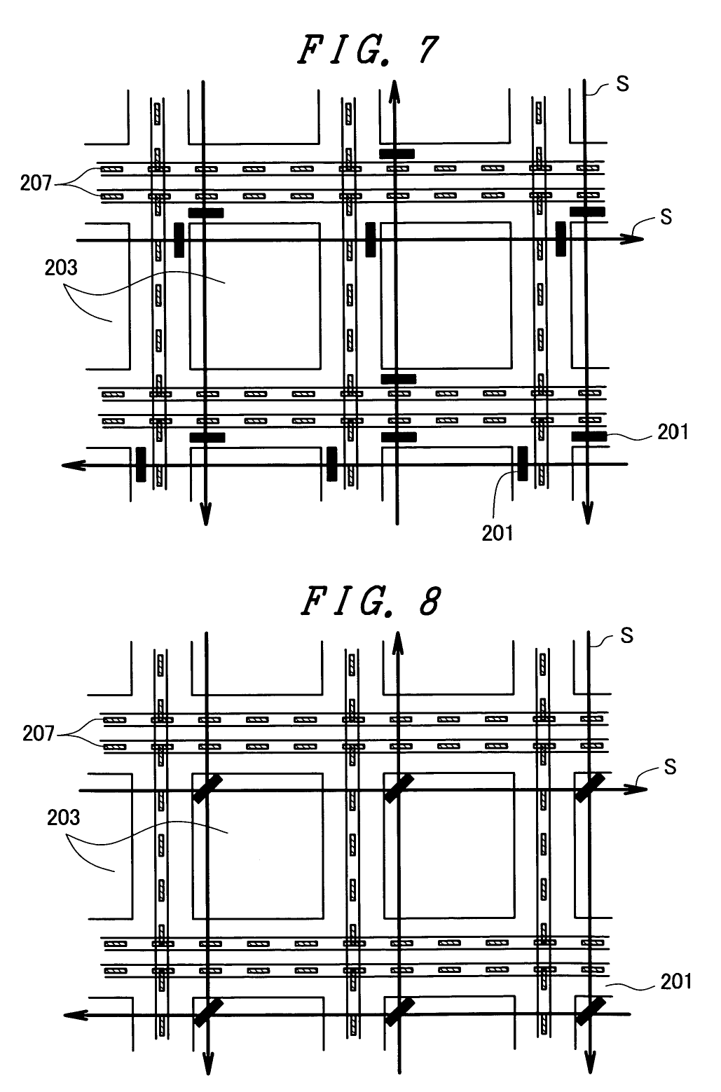

FIG. 6 is a view for schematically explaining the embodiment 1 of a layout of the bank on a substrate for a display device of the present invention, wherein FIG. 6 shows a plan view, a cross-sectional view taken along a line A-A′ in the plan view, and a cross-sectional view taken along a line B-B′ in the plan view. Here, in the embodiments explained hereinafter including the embodiment 1, the explanation is made with respect to a case in which the projecting portions are formed on a glass substrate 101. The present invention is also applicable to a case in which the projecting portions are formed of a background film which is formed on the glass substrate 101. Further, FIG. 7 is a plan view sowing a portion of FIG. 6 in an enlarged manner. In the embodiment 1, the island-like bank 201 which is formed on the glass substrate 101 is arranged orthogonal to the scanning direction S of the laser beams. The glass substrate 101 is a multiple-piece substrate from which a large number of active substrates of the liquid crystal display device are fabricated at one time. In the drawings, portions indicated by numeral 203 are thin film transistor (TFT) forming regions.

As shown in FIG. 7 in an enlarged manner, the scanning is performed by reciprocating the laser beams in the respective directions orthogonal to high mobility thin film transistor forming portions positioned at two sides in the thin film transistor (TFT) forming regions 203. The scanning directions of the laser beams are indicated by symbol S. The island-like banks 201 are arranged at positions where the scanning directions S of the laser beams intersect the island-like banks 201. Further, the island-like banks 201 are arranged inside scribe lines 207 indicated by a bold line for separating the substrate into substrates of the individual liquid crystal display devices.

Even when the aggregation is generated in a certain thin film transistor forming region which is scanned with the laser beams, at a point of time that the laser beams get over the island-like banks 201 which are arranged directly in front of the thin film transistor forming region to be scanned by laser beams next time, the aggregation is stopped and, thereafter, the normal strip crystals are formed. According to the embodiment 1, it is possible to provide the fabrication method which can acquire the display-device-use substrate which is strip crystallized such that the generation of peeling of the semiconductor is minimized by suppressing the generation of the aggregation at the time of crystallization by the radiation of continuous oscillation laser beams, and the high-quality display device which is fabricated by the fabrication method.

### EMBODIMENT 2

FIG. 8 is a plan view which schematically shows the embodiment 2 of the layout of the banks on the substrate for display device according to the present invention. Island-like banks 201 are formed at positions where the island-like banks 201 intersect the respective two scanning directions of laser beams at an angle of 45° at corner portions of two sides of the thin film transistor (TFT) forming regions 203 of each display device. The scanning is performed by reciprocating the laser beams indicated by the scanning lines S in the directions respectively including the high-mobility thin film transistor forming portions. Other constitutions are substantially equal to the corresponding constitutions explained in conjunction with FIG. 7.

Even when the aggregation is generated in a certain thin film transistor forming region which is scanned with the laser beams, at a point of time that the laser beams get over the island-like banks 201 which are arranged directly in front of the thin film transistor forming region to be scanned by laser beams next time, aggregation is stopped and, thereafter, the normal strip crystals are formed. According to the embodiment 2, it is possible to provide the fabrication method which can acquire the display-device-use substrate which is strip crystallized such that the generation of peeling of the semiconductor is minimized by suppressing the generation of the aggregation at the time of crystallization by the radiation of continuous oscillation laser beams, and the high-quality display device which is fabricated by the fabrication method.

### EMBODIMENT 3

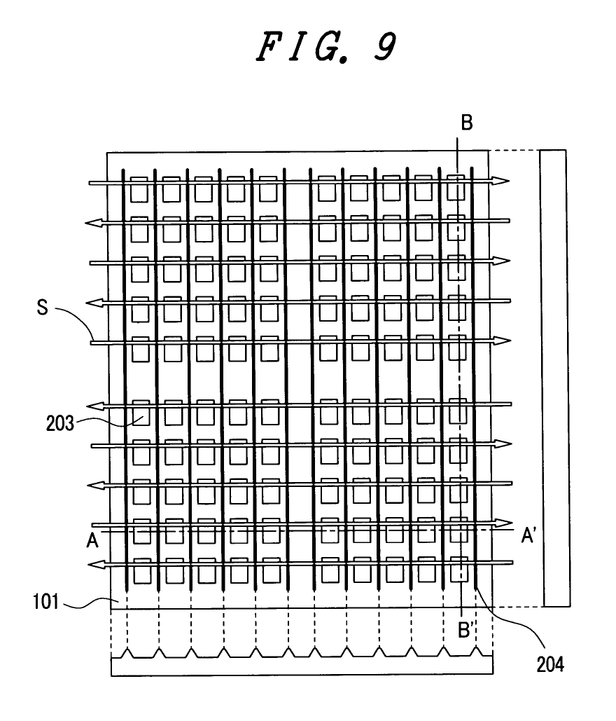

FIG. 9 is a view for schematically explaining the embodiment 3 of a layout of the bank on a substrate for a display device of the present invention, wherein FIG. 9 shows a plan view, a cross-sectional view taken along a line A-A′ in the plan view, and a cross-sectional view taken along a line B-B′ in the plan view. The embodiment 3 is characterized in that stripe-shaped banks 204 which are formed on the glass substrate 101 are arranged orthogonal to the scanning direction S of the laser beams. The glass substrate 101 is a multiple-piece substrate from which a large number of active substrates of the liquid crystal display device are fabricated at one time. In the drawings, portions indicated by numeral 203 are thin film transistor (TFT) forming regions.

The stripe-shaped banks 204 are formed in a line shape (in a stripe-shaped shape) in the direction orthogonal to the scanning direction S of laser beams and at positions where each thin film transistor forming region (active substrate of individual display device) is sandwiched from one direction. The scanning is performed by reciprocating the laser beams indicated by the scanning lines S in the directions respectively including the high-mobility thin film transistor forming portions. Other constitutions are substantially equal to the corresponding constitutions explained in conjunction with FIG. 7 and FIG. 8.

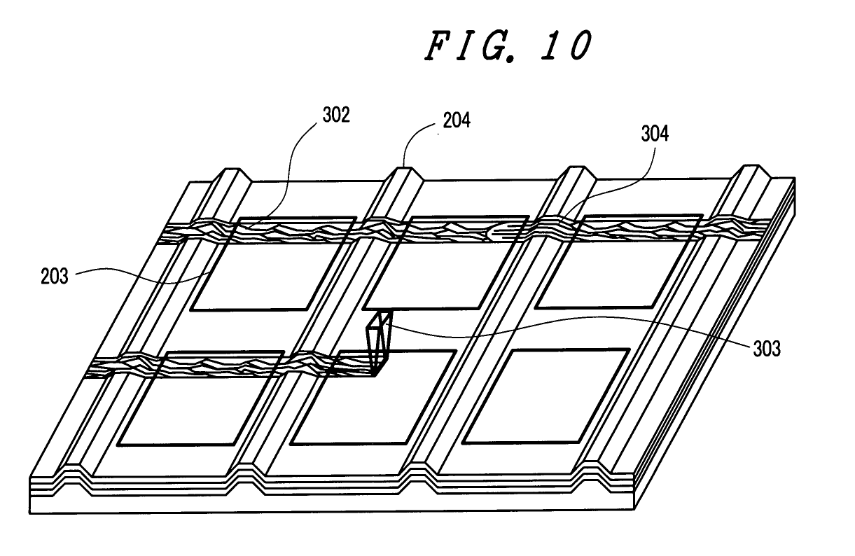

FIG. 10 is a schematic view for explaining the generation of aggregation in the embodiment 3 shown in FIG. 9 and the suppression of the generation of aggregation. The scanning by the laser beams 303 is performed orthogonal to the stripe-shaped banks 204 and the laser beams 303 melts and reforms the silicon substrate film formed on the substrate into the stripe-shaped silicon crystals 302 having the longitudinal direction thereof in the laser scanning direction. When the aggregation 304 is generated during the reforming of the silicon substrate film by the laser scanning, the aggregation 304 creeps up an ascending inclined surface of the bank 204 and, subsequently, returns again to the normal melting and strip crystallization at a point of time that the aggregation descends a descending inclined surface and the reforming process is executed.

In this manner, even when the aggregation is generated in a certain thin film transistor forming region which is scanned with the laser beams, at a point of time that the laser beams get over the stripe-shaped banks 204 which is arranged directly in front of the thin film transistor forming region to be scanned by the laser beams next time, the aggregation is stopped and, thereafter, the normal strip crystal are formed. According to the embodiment 3, it is possible to provide the fabrication method which can acquire the display-device-use substrate which is strip crystallized such that the generation of peeling of the semiconductor is minimized by suppressing the generation of the aggregation at the time of crystallization by the radiation of continuous oscillation laser beams, and the high-quality display device which is fabricated by the fabrication method.

### EMBODIMENT 4

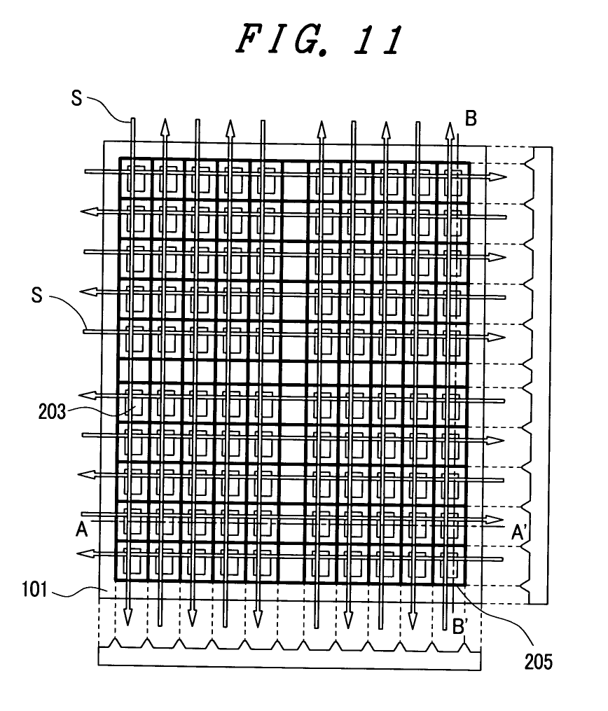

FIG. 11 is a view for schematically explaining the embodiment 4 of a layout of the bank on a substrate for a display device of the present invention, wherein FIG. 11 shows a plan view, a cross-sectional view taken along a line A-A′ in the plan view, and a cross-sectional view taken along a line B-B′ in the plan view. The embodiment 4 is characterized in that grid-shaped banks 205 which are formed on the glass substrate 101 are arranged longitudinally as well as laterally. The scanning by the laser beams is performed in two directions orthogonal to thin film transistor forming regions 203. Respective sides of the grid-shaped bank 205 are orthogonal to the scanning directions S of the laser beams. The glass substrate 101 is also a multiple-piece substrate from which a large number of active substrates of the liquid crystal display device are fabricated at one time.

The respective banks 205 which intersect in a grid array are formed in the directions respectively orthogonal to the scanning directions S of the laser beams which perform scanning longitudinally and laterally and sandwich each thin film transistor forming region (the active substrate of each display device) from two directions. The laser beams which are indicated by the scanning direction S reciprocally scan portions including the high-mobility thin film transistor forming portions. Other constitutions are substantially equal to the corresponding constitutions explained in conjunction with the above-mentioned respective embodiments.

According to the embodiment 4, it is also possible to provide the fabrication method which can acquire the display-device-use substrate which is strip crystallized such that the generation of peeling of the semiconductor is minimized by suppressing the generation of the aggregation at the time of crystallization by the radiation of continuous oscillation laser beams, and the high-quality display device which is fabricated by the fabrication method.

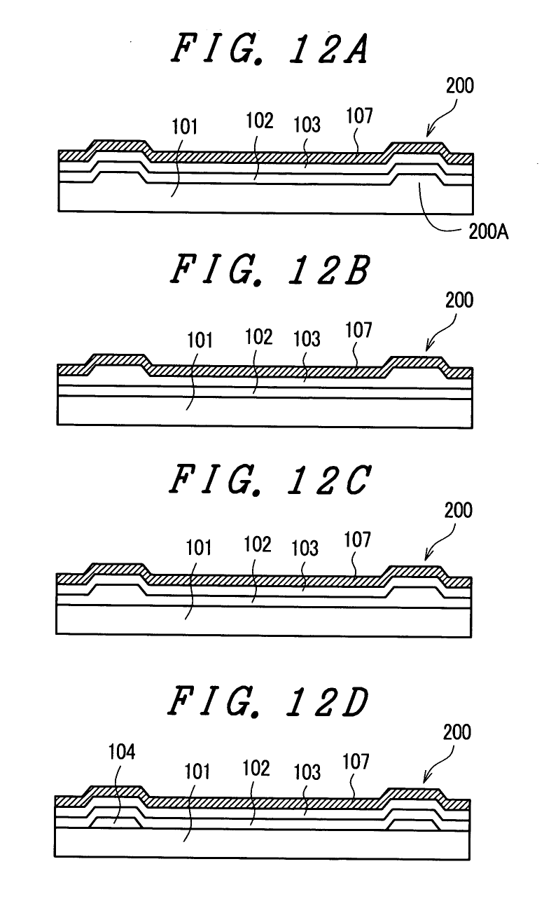

FIG. 12A to FIG. 12D are views for explaining various kinds of cross sections of the glass substrate on which the silicon film is formed in the above-mentioned respective embodiments of the present invention. FIG. 12A shows a substrate which is equal to the substrate explained in conjunction with FIG. 2A previously, wherein the projecting portions 200A are formed on the glass substrate 101. FIG. 12A shows a state in which the silicon nitride film 102 and the silicon oxide film 103 are formed on the substrate as the background film and the silicon base film 107 is formed to cover the background film.

FIG. 12B shows a state in which, as has been explained in conjunction with FIG. 2B, the silicon oxide film 103 which constitutes the upper layer of the background film is patterned to form the projecting portions, these projecting portions are formed into the banks 200, and the silicon base film 107 is formed to cover the banks 200. Further, FIG. 12C shows a state in which, as has been explained in conjunction with FIG. 2C, the silicon nitride film 102 which constitutes the lower layer of the background film is patterned to form the projecting portions, these projecting portions are formed into the banks 200, and the silicon base film 107 is formed to cover the banks 200. Further, FIG. 12D shows a state in which, as has been explained in conjunction with FIG. 2D, the insulation film or the metal film 104 different from the background film is patterned to form the projecting portions on the glass substrate 101, these projecting portions are formed into the banks 200, and the silicon base film 107 is formed to cover the banks 200.

The substrates in the above-mentioned embodiments 1 to 4 may adopt any one of the constitutions shown in FIG. 12A, FIG. 12B, FIG. 12C and FIG. 12D. Further, the banks 200 may be arranged within the thin film transistor region of the individual active substrate. Still further, the strip crystal silicon film may not be continuously formed and may be formed of blocks.

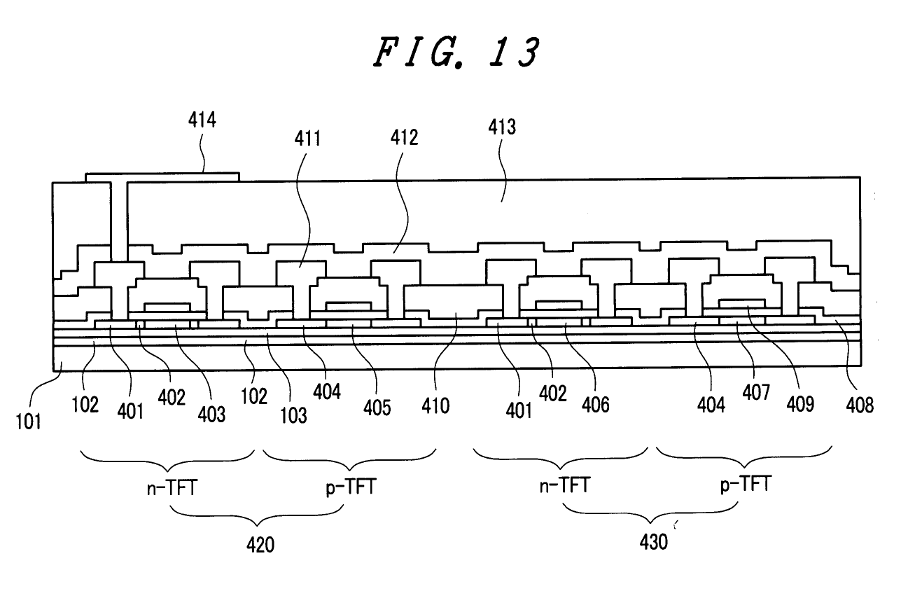

FIG. 13 is a cross-sectional view for schematically explaining the constitution of an essential part of the active substrate which constitutes the display device of the present invention. FIG. 13 shows a state in which, as various kinds of thin film transistor circuits which are formed on the substrate, a pixel circuit 420 and a drive circuit 430 which requires high-speed driving are built into semiconductor films having different crystallization. In the region in which the pixel circuit 420 is built, the small-particle-size silicon crystal film is formed into diffusion layers, LDD layers and channel layers of the thin film transistors n-TFT and p-TFT, while in the region in which the drive circuit 430 is built, the large-particle-size silicon crystal film, that is, the strip crystal silicon film is formed into diffusion layers, LDD layers and channel layers of the thin film transistors n-TFT and p-TFT.

In conjunction with FIG. 13, the constitution of the display device is explained together with the fabrication process. First of all, the silicon nitride film 102 and the silicon oxide film 103 which constitutes the background film are formed on the substrate 101, and the silicon substrate film made of poly-silicon is formed on the silicon nitride film 102 and the silicon oxide film 103. Here, it may be possible that the amorphous silicon film is formed in place of the poly-silicon film and, thereafter, the amorphous silicon film is radiated with excimer laser beams to be formed into the poly-silicon film. Next, the portion in which the thin film transistor of the drive circuit 302 is built is radiated with the continuous oscillation laser beams thus forming the strip crystal silicon film.

Using an alignment mark formed on the substrate as a reference, the silicon film is formed in an island shape such that the portion in which the thin film transistor for high-speed driving is built by a photolithography method is accommodated in the strip crystal silicon film. Succeeding processes are substantially equal to the known corresponding processes. That is, first of all, a gate insulation film 408 is formed to cover the island-like formed silicon film and the first doping treatment (NE) is applied to the whole surface of the silicon film. Next, a photo resist is applied to the gate insulation film 408, patterning is performed to form a mask, and the second doping treatment (NES) is applied to a region 406 which forms the n-type thin film transistor (n-TFT) with the strip crystal silicon film using the mask.

Next, using the photo resist as a mask, the third doping treatment (PE) is applied to a region 405 which forms the p-type thin film transistor (p-TFT) with the p-Si film. Subsequently, the fourth doping treatment (PES) is applied to a region 407 which forms the p-type thin film transistor (p-TFT) with the strip crystal silicon film using the photo resist as a mask.

An electrode film for gate electrodes is formed, a photo resist pattern is formed on the electrode film, and gate electrodes 409 are formed by wet etching. Here, the gate electrode 409 has sides thereof etched by approximately 1.0 μm, for example, by side etching using the resist pattern. Next, using the photo resist which is previously used for forming the gate electrodes as it is, the fifth doping treatment (N) is applied to the whole surface of the substrate. Subsequently, the photo resist is peeled off and, thereafter, the sixth doping treatment (NM) is applied to the whole surface of the substrate thus forming source/drain regions 401 of the n-TFT having the self-aligned LDD (Light Doped Drain) 402.

Next, using the photo resist as a mask, the seventh doping treatment (P) is applied to the region where the p-TFT is formed as the counter doping for the fifth and sixth doping treatments which are performed prior to the seventh doping treatment thus forming source/drain regions 404 of the p-TFT. Next, an insulator which becomes an interlayer insulation film 410 is formed and, thereafter, annealing is applied to the stacked structure by heat treatment or the like thus performing the activation treatment of impurities introduced into the silicon semiconductor layer by the above-mentioned first to seventh doping treatment.

Contact holes are formed in the interlayer insulation film 410 and metal lines 411 are formed. Next, an interlayer insulation film 412 which constitutes a passivation layer is formed and, thereafter, a contact hole is formed in the interlayer insulation film 412. Subsequently, annealing treatment is performed to terminate a dangling bond of the silicon semiconductor film. Next, a photosensitive organic leveling film 413 is formed and, simultaneously, a contact hole is formed. Finally, pixel electrodes 414 which are connected with the metal lines 411 via the contact holes are formed on the leveling film 413.

The display device of the present invention may preferably be an image display device which includes pixels which are arranged in a matrix array and the scanning drive circuit and the signal line drive circuit which perform the matrix driving of the pixels on the substrate, wherein at least the signal line drive circuit includes the thin film transistor which uses the strip-crystal semiconductor thin film as the channel. Further, besides the pixels, the scanning drive circuit and the signal line drive circuit, it may be possible to form a circuit having a thin film transistor which uses a strip-crystal semiconductor thin film as a channel thereof. Still further, it may be possible to use this semiconductor thin film in the thin film transistor which constitutes the pixel or the scanning line drive circuit.

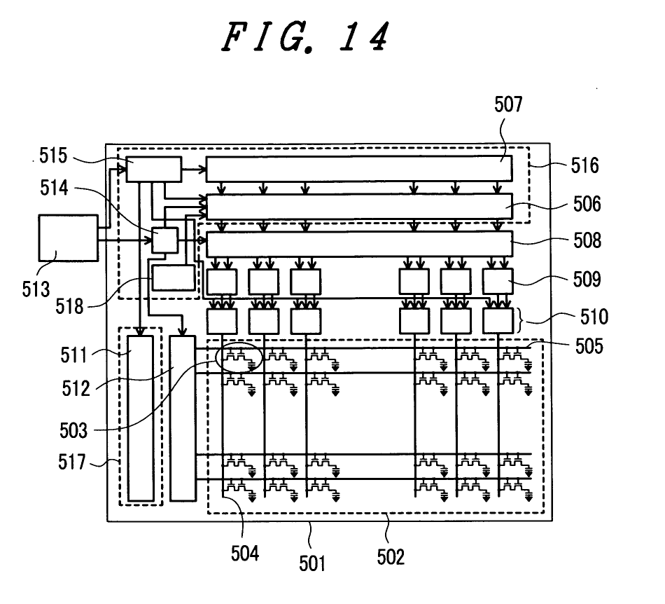

FIG. 14 is an explanatory view of a constitutional example of circuits which are formed on a glass substrate of a display device fabricated by the fabrication method of the present invention. A glass substrate 501 which corresponds to the glass substrate 101 explained in the above-mentioned respective embodiments is also referred to as an active substrate or a thin film transistor substrate (TFT substrate). The glass substrate 501 is an active substrate for a line-sequential-type liquid crystal display device. Thin film transistor (TFT) circuits which are formed on the glass substrate 501 form a pixel region 502 by most portions thereof.

Pixels (pixel circuits) 503 which are arranged in a matrix array in the pixel region 502 are formed on intersecting portions of data lines 504 and gate lines 505. The pixel 503 is constituted of a thin film transistor TFT which functions as a switch and a pixel electrode. Outside the pixel region 502 on the glass substrate 501, a drive circuit region in which circuits for supplying drive signals to a large number of pixels formed in the pixel region 502 are formed is arranged.

On one long side (an upper side in FIG. 14) of the pixel region 502, a shift register 507 having a role to allow a D/A converter 506 to sequentially read digitalized display data, the D/A converter 506 which outputs the digitalized display data as gray scale voltage signals, a level shifter 508 which acquires desired gray scale voltages by amplifying the gray scale signals from the D/A converter 506, a buffer circuit 509, and a sampling switch 510 which inverts the polarity of the gray scale voltage between the neighboring pixels.

On one short side (a left side in FIG. 14) of the pixel region 502, a shift register 511, a level shifter 512 which sequentially open gates of the thin film transistors TFT which constitute the pixel electrodes 503 are arranged.

Further, around a group of these circuits, an interface 514 which takes image data supplied from signal sources (a system LSI) 513 to the display and performs the signal conversion, a gray scale signal generator 518, a clock signal generator 515 which generates clock signals for controlling timing of respective circuits and the like are arranged.

Among the group of these circuits, the circuits such as the interface 514, the clock signal generator 515, the drain-side shift register 507, the gate-side shift register 511, the D/A converter 506 process digital signals and hence, these circuits are required to satisfy a demand for high-speed driving and are also required to satisfy a demand for low power driving to realize the low power consumption. On the other hand, the pixels 503 are circuits for applying voltages to the liquid crystal and for modulating the transmissivity of the liquid crystal and hence, it is inevitably necessary to drive the pixels at high voltages to generate gray scales. Further, to hold the voltages for fixed times, the transistors for switching are required to satisfy a low leak current. The drain-side level shifter 508, the gate-side level shifter 512, the buffer circuit 509 and the sampling switch 510 which are arranged between the group of low voltage drive circuits and the group of high voltage drive circuits are required to be driven at high voltages to supply analogue signals of high voltages to the pixels.

In this manner, to prepare the circuits for image display on the glass substrate, it is necessary to simultaneously mount the thin film transistors of the plurality of specifications which are contradictory to each other. Accordingly, the above-mentioned high-quality polycrystalline silicon film (strip crystal silicon film) is adopted in portions of the interface 514, the clock signal generator 515, the drain-side shift register 507, the gate-side shift register 511, and the D/A converter 506. Ranges within which the high-quality polycrystalline silicon film is adopted are indicated by numerals 516, 517.

Due to the above-mentioned group of thin film transistors, although the group of high-speed circuits are mounted as an LSI chip on an outer periphery of the image region 502 which is formed on the glass substrate which constitutes the active substrate conventionally, it is possible to directly form the group of highs-speed circuits in the inside of the same glass substrate 501. Accordingly, the reduction of the LSI chips, and the reduction of the non-pixel region of the panel peripheral portion, that is, the enlargement of the pixel region can be realized. Further, the customization of circuit which has been performed at a point of time of designing or fabrication of the LSI chips can be realized in the panel fabrication step. Here, the present invention is applicable to the semiconductor circuit LSI chip and the semiconductor circuit LSI chip may be mounted on the panel peripheral portion in the same manner as the conventional technique.

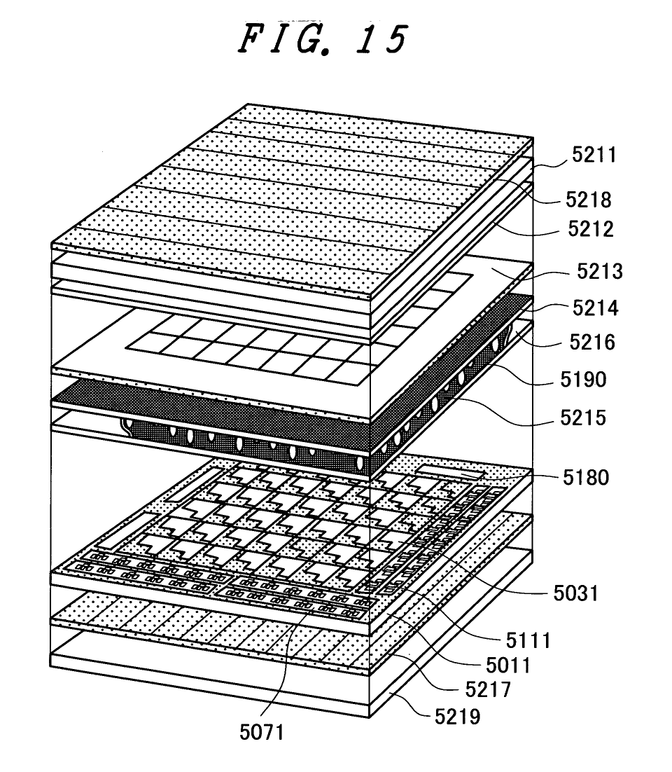

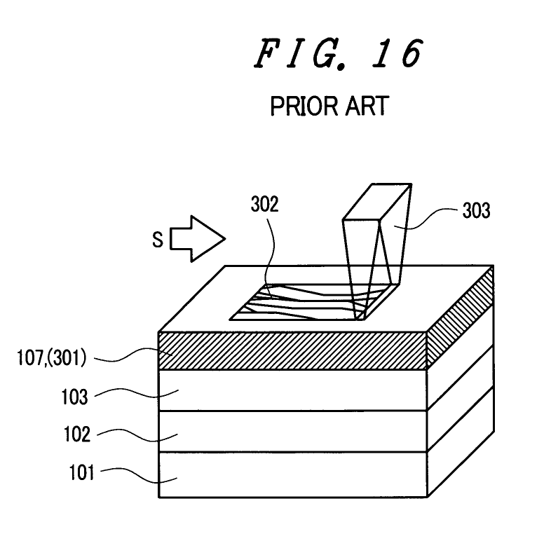

FIG. 15 is a schematic view for explaining a constitutional example of a liquid crystal display device which constitutes the embodiment of the display device of the present invention. On a glass substrate 5011 corresponding to the glass substrate 501 shown in FIG. 14 which constitutes the active substrate, a plurality of pixel electrodes 5031 which are arranged in a matrix array, circuits 5071 and 5111 which input display signals to the pixel electrodes, and a group of other peripheral circuits which is necessary for image display are formed and, thereafter, an orientation film 5190 is applied by a printing method thus forming an active matrix substrate.

On the other hand, counter electrodes 5212, color filters 5213 and an orientation film 5214 are applied in the same manner to the glass substrate 5211 which constitutes a color filter substrate, and the color filter substrate is adhered to the active matrix substrate. Liquid crystal 5215 is filled between the orientation films 5190, 5214 which face each other by vacuum injection and the liquid crystal is sealed by a sealing material 5216. Thereafter, polarizers 5217, 5218 are respectively adhered to outer surfaces of the first glass substrate 5011 and the second glass substrate 5211. Then, a backlight 5219 is arranged on a back surface of the active matrix substrate thus completing the liquid crystal display device.

According to this liquid crystal display device, it is possible to directly form the pixels, the drive circuits which drive the pixels and other peripheral circuits on the active matrix substrate corresponding to required characteristics of these parts and hence, it is possible to acquire the liquid crystal display device having the favorable display quality which can enhance the pixel region and exhibits the high-speed driving and the high resolution.

The present invention may be applicable to an organic EL display device and other similar active-matrix-type various display devices or various kinds of semiconductor devices.

What is claimed is:

1. A fabrication method of a display device which includes a substrate, an insulation film formed on the substrate, and as semiconductor formed on the insulation film, the fabrication method comprising:
a bank forming step in which a bank is formed on the substrate or the insulation film;
a semiconductor film forming step in which a semiconductor film is formed such that the semiconductor film covers the bank and a flat portion except for the bank; and
a strip crystal forming step in which while radiating the continuous oscillation laser beams to the semiconductor film, the scanning is performed traversing the bank in the direction which intersects the longitudinal direction of the bank at an angle of 30 degrees or more and 90 degrees or less thus forming strip crystal on the semiconductor film.

2. A fabrication method of a display device according to claim 1, wherein the strip crystal forming step is a step in which the strip crystal is formed such that while radiating the continuous oscillation laser beams to the semiconductor film, the scanning is performed traversing the bank in the direction which intersects the longitudinal direction of the bank at an angle of 60 degrees or more and 90 degrees or less thus forming strip crystal on the semiconductor film.

3. A fabrication method of a display device according to claim 1, wherein the strip crystal forming step is a step in which the strip crystal is formed such that while radiating the continuous oscillation laser beams to the semiconductor film, the scanning is performed traversing the bank in the direction which intersects the longitudinal direction of the bank at an angle of 30 degrees or more and 60 degrees or less thus forming strip crystal on the semiconductor film.

4. A fabrication method of a display device according to claim 1, wherein the fabrication method includes a cutting step in which the substrate is cut into a plurality of display devices, and the bank is formed along the cut portions.

5. A fabrication method of a display device according to claim 4, wherein the bank is formed in the vicinity of the cut portions.

6. A fabrication method of a display device according to claim 1, wherein a height of the bank is set to 20 nm or more.

7. A fabrication method of a display device according to claim 1, wherein a tapered angle of the bank is set to 10 degrees or more.

8. A fabrication method of a display device according to claim 1, wherein the scanning of the continuous oscillation laser beams is performed by moving either one of the radiation beams of the continuous oscillation laser or the substrate.

9. A fabrication method of a display device according to claim 1, wherein the continuous oscillation laser beams are radiated to the semiconductor film while modulating the continuous oscillation laser beams into pulses.

10. A display device comprising:
a substrate;
an insulation film which is formed on the substrate; and
a semiconductor film which is formed on the insulation film, wherein
the semiconductor film includes strip crystal,
the substrate or the insulation film has a bank, and
the longitudinal direction of the bank intersects an extension of the strip crystal in the longitudinal direction at an angle of 30 degrees or more and at an angle of 90 degrees or less.

11. A display device according to claim 10, wherein the longitudinal direction of the bank intersects an extension of the strip crystal in the longitudinal direction at an angle of 60 degrees or more and 90 degrees or less.

12. A display device according to claim 10, wherein the longitudinal direction of the bank intersects an extension of the strip crystal in the longitudinal direction at an angle of 30 degrees or more and 60 degrees or less.

13. A display device according to claim 10, wherein the bank is formed along a side of the substrate.

14. A display device according to claim 13, wherein the bank is formed along a side of the substrate and may be formed at a position in the vicinity of the side of the substrate.

15. A display device according to claim 10, wherein the strip crystal is formed at a flat portion.

16. A display device according to claim 10, wherein a height of the bank is set to 20 nm or more.

17. A display device according to claim 10, wherein a tapered angle of the bank is set to 10 degrees or more.
